(19) United States
(12) Patent Application Publication
(10) Pub. No.: US 2004/0144977 A1
(43) Pub. Date: Jul. 29, 2004

(54) Semiconductor wafer with a thin epitaxial silicon layer, and production process

(75) Inventors: Reinhard Schauer, Laufen (DE); Markus Blietz, Tittmoning (DE); Wilfried von Ammon, Hochburg/Ach (AT); Rudiger Schmolke, Burghausen (DE)

Correspondence Address: Collard & Roe, P.C., 1077 Northern Boulevard, Roslyn, NY, 11576, US

(73) Assignee: WACKER SILTRONIC GESELLSCHAFT FUR HALBLEITERMATERIALIEN AG

(21) Appl. No.: 10/756,035

(22) Filed: Jan. 13, 2004

Related U.S. Application Data
(62) Division of application No. 09/890,656, filed on Aug. 2, 2001.

(30) Foreign Application Priority Data
Mar. 4, 1999 (DE) 199 09 557.4
Feb. 3, 2000 (DE) 100 04 623.1
Mar. 2, 2000 (WO) PCT/EP00/01800

(51) Int. Cl. H01L 29/04

(52) U.S. Cl. 257/56

(57) ABSTRACT

A semiconductor wafer is made of a silicon substrate wafer and an epitaxial silicon layer deposited thereon. The substrate wafer has a specific resistance of 0.1 to 50 Ωcm, an oxygen concentration of less than 7.5*10¹⁷ atcm⁻³ and a nitrogen concentration of 1*10¹³ to 5*10^{15 atcm}⁻³. The epitaxial layer is 0.2 to 1.0 μm thick and has a surface on which fewer than 30 LLS (localized light scattering) defects which are greater in size than 0.085 μm can be detected. A method for producing the semiconductor wafer has a sequence of steps for providing the substrate wafer with the aforementioned features; heating the substrate wafer in a deposition reactor to a deposition temperature of at least 1120° C.; and depositing the epitaxial layer thereon with a thickness of 0.2 to 1.0 μm, immediately after the deposition temperature has been reached.

The invention relates to a semiconductor wafer with a thin epitaxial layer, and a process for producing the semiconductor wafer by depositing the layer on a substrate wafer made of silicon.

At the present time intensive investigations are under way with the aim of establishing which features semiconductor wafers with an epitaxial layer have to have in order to qualify them as a base material for the production of modern CMOS components. According to the publication in Jpn. J. Appl. Phys. Vol. 36 (1997), pp. 2565-2570, a semiconductor wafer comprising a p⁻-doped substrate wafer and a likewise p⁻-doped epitaxial layer having a thickness of 1 μm is particularly suitable for large scale integrated CMOS applications. This appraisal is also supported by the publication in Electrochemical Society Proceedings Volume 98-1, pp. 855-861. However, this paper also draws attention to light-scattering defects (light point defects) on the surface which occur in a semiconductor wafer with a thin epitaxial layer but do not adversely affect the GOI (gate oxide integrity). The abovementioned defects are called LLSs (localized light scatterers) by experts. Despite their indifferent behavior with regard to the GOI, the LLSs are undesirable to manufacturers of integrated circuits, which is also demonstrated by the fact that the ITRS (International Roadmap For Semiconductors) demands that the number of LLSs with a size of greater than or equal to 0.085 μm be less than or equal to 38 per semiconductor wafer with an epitaxial layer. This requirement applies to 0.18 μm technology and it must be assumed that as miniaturization advances (0.13 μm and below), an even more stringent requirement will be imposed on the number of LLSs. Moreover, the limit value of 38 LLSs represents a maximum value and it should be taken into account that the number required for an industrial process capability must be significantly less than that.

The object of the invention was to provide a semiconductor wafer with an epitaxial layer which is suitable for modern CMOS applications, has a particularly small number of LLSs and requires comparatively low production costs. The object of the invention is, moreover, to specify a process for producing the semiconductor wafer.

The invention relates to a semiconductor wafer, comprising a substrate wafer made of silicon and an epitaxial layer deposited thereon, which is characterized in that the substrate wafer has a resistivity of from 0.1 to 50 Ωcm, an oxygen concentration of less than 7.5*10¹⁷ atcm⁻³ and a nitrogen concentration of from 1*10⁻¹³ to 5*10¹⁵ atcm⁻³, and the epitaxial layer has a thickness of from 0.2 to 1.0 μm and has a surface on which fewer than 30 LLS defects with a size of more than 0.085 μm can be detected.

The invention also relates to a process for producing a semiconductor wafer with an epitaxial layer by depositing the layer on a substrate wafer made of silicon, which is characterized by a sequence of steps comprising:

the provision of the substrate wafer, the substrate wafer having a resistivity of from 0.1 to 50 Ωcm, an oxygen concentration of less than 7.5*10¹⁷ atcm⁻³ and a nitrogen concentration of from 1*10¹³ to 5*10¹⁵ atcm⁻³;

the heating of the substrate wafer in a deposition reactor to a deposition temperature of at least 1120° C.; and

immediately after the deposition temperature has been reached, the deposition of the epitaxial layer with a thickness of from 0.2 to 1.0 μm.

Investigations by the inventors have revealed that the combination of the abovementioned process steps and the fact of the abovementioned material parameters being taken into account afford a semiconductor wafer with an epitaxial layer which wholly satisfies the requirements imposed. With regard to the supposition that can be derived from the abovementioned prior art, according to which the number of LLSs can be kept low only by having the thickest possible epitaxial layer (>=3 μm), the result of the investigations is surprising because it shows that extremely low LLSs densities are possible even with layer thicknesses of from 0.2 to 1 μm. The small layer thicknesses and the fact that the proposed process manages without a so-called baking step before the deposition of the epitaxial layer account for a distinct cost advantage over known processes. Thus, the throughput of semiconductor wafers per hour can be increased by up to threefold.

In order to achieve the required properties with regard to the LLSs density, a substrate wafer is required which has a resistivity of from 0.1 to 50 μcm, an oxygen concentration of less than 7.5*10¹⁷ atcm⁻³, particularly preferably of less than 6.5*10¹⁷ atcm⁻³, and a nitrogen concentration of from 1*10¹³ to 5*10¹⁵ atcm⁻³, particularly preferably of from 1*10¹⁴ to 5*10¹⁴ cm⁻³, and is preferably cut from a single crystal that has been pulled according to the Czochralski method. As far as the deposition of the epitaxial layer is concerned, it is important that deposition be effected at a deposition temperature of from 1120 to 1200° C., with account being taken of the type of substrate wafer.

In this case, an elevated deposition temperature has the fundamental advantage of reducing so-called “area counts”, that is to say large defects on the epitaxial layer which can lead to losses in yield for semiconductor component manufacturers.

A single crystal from which substrate wafers having the desired properties can be separated can be produced for example according to a process as described in DE-198 23 962 A. In the process, the single crystal is pulled from a melt according to the Czochralski method and, during this, is additionally doped with nitrogen. In accordance with one embodiment of the invention, at least 90 min elapse before single crystal material that has just crystallized has passed through the temperature range from 1050 to 900° C. This is normally the case when the single crystal cools by itself, in other words forced cooling of the single crystal is dispensed with. The epitaxial layer is deposited on a substrate wafer which originates from a single crystal pulled in such a way and is referred to below as a type I substrate wafer, at a deposition temperature of from 1120 to 1170° C., preferably from 1130 to 1160° C.

In accordance with a further embodiment of the invention, the single crystal is pulled according to the Czochralski process and subjected to forced cooling in this case. As a result, at most 40 min elapse before single crystal material that has just crystallized has passed through the temperature range from 1050 to 900° C. The pulling installation must be provided with a forced cooling arrangement in order to ensure that the single crystal is cooled rapidly. A cooling apparatus in accordance with EP-725 169 A1 is preferably used during the pulling of the single crystal. The epitaxial layer is deposited on a substrate wafer which originates from a single crystal pulled in such a way and is referred to below as a type II substrate wafer, at a deposition temperature of from. 1120 to 1200° C., preferably from 1130 to 1190° C., which corresponds to a distinctly wider process window in the epitaxial deposition by comparison with type I and thus distinctly facilitates optimization with regard to economic efficiency.

For the deposition of the epitaxial layer, the substrate wafer is loaded into a deposition reactor. A single-wafer reactor with an automatic wafer loading and discharging mechanism is preferred. The temperature in the reactor should already have a comparatively high value, at the very least 800° C., in the course of loading. A temperature of at least 850° C. is preferred, and a temperature of at least 900° C. is particularly preferred.

The substrate wafer is subsequently heated to a deposition temperature in a gas atmosphere. The gas atmosphere is preferably selected from a group of gases which includes hydrogen, argon, helium and any desired mixtures of the gases mentioned. A gas atmosphere of hydrogen is particularly preferred.

As soon as the deposition temperature has been reached, the deposition of the epitaxial layer with a thickness of from 0.2 to 1 μm, preferably from 0.3 to 0.6 μm, is begun by an atmosphere of deposition gas and dopant gas being added to the gas atmosphere. A so-called baking step, in which the substrate wafer is kept at deposition temperature in the gas atmosphere for a period of time, for example from 5 to 60 s, is not performed. The deposition gas is preferably selected from a group of gases which includes trichlorosilane, silane, dichlorosilane, tetrachloro-silane and any desired mixtures of the gases mentioned. Trichlorosilane is particularly preferred. The dopant gasis preferably selected from a group of gases which includes diborane, phosphine and arsine. Diborane is particularly preferred.

The deposition time is preferably from 1 to 10 s, particularly preferably from 1 to 5 s. Preference is given, moreover, to setting the resistivity of the epitaxial layer to from 0.5 to 50 Ωcm.

After the deposition of the epitaxial layer, the semiconductor wafer, preferably in an atmosphere of hydrogen, is brought to a discharge temperature of preferably from 850 to 950° C. and discharged from the deposition reactor.

It is possible to coat at least 50, preferably up to 200, substrate wafers in succession before the deposition reactor has to be cleaned with an etching gas or a plasma.

Semiconductor wafers produced according to the invention were compared with conventionally produced semiconductor wafers with regard to LLSs.

### EXAMPLE

The semiconductor wafers produced according to the invention comprised a substrate wafer made of silicon with a resistivity of 12 Ωcm (p⁻-type doping), on which an epitaxial layer having a layer thickness of 0.5 μm and a resistivity of 1.5 Ωcm had been grown. The deposition temperature was from 1130 to 1190° C. The substrate wafers were of type I and type II.

In the case of the conventionally produced semiconductor wafers, the substrate wafers originated from a single crystal pulled according to the Czochralski method without any doping with nitrogen. Substrate wafers from a single crystal pulled in this way are referred to below as reference I substrate wafers, if the single crystal. had been cooled without forced cooling. In the case of the substrate wafers referred to as reference II substrate wafers, the corresponding single crystal was subjected to forced cooling. The epitaxial layer was deposited under the same conditions as those prevailing for the semiconductor wafers produced according to the invention.

Tables 1 and 2 below verify that the combined selection of substrate wafer and deposition temperature is of crucial importance when what matters is minimizing the number of LLSs.

TABLE 1

| | Type I substrate | Reference I |
|---|---|---|
| LLS > 0.085 μm | wafer*⁾ | substrate wafer*⁾ |
| 1130° C. deposition | 18 (+) | 40 (−) |
| temp. | | |
| 1190° C. deposition | 98 (−) | 1167 (−) |
| temp | | |

TABLE 2

| | Type II substrate | Reference II |
|---|---|---|
| LLS > 0.085 μm | wafer*⁾ | substrate wafer*⁾ |
| 1130° C. deposition | 15 (+) | 820 (−) |
| temp. | | |
| 1190° C. deposition | 12 (+) | 1389 (−) |
| temp | | |

*⁾+/−: satisfies/does not satisfy the requirements of the most modern generations of components.

Furthermore, the dramatic throughput advantage of the wafers produced according to the invention compared with wafers that are epitaxially coated in a conventional manner can be seen from Table 3. The throughput advantage results directly in a corresponding cost advantage.

TABLE 3

| | Semiconductor | |
|---|---|---|
| | wafer according | |
| | to the invention | Reference wafer***) |
| Throughput | 90 | 30 |
| (wafers/hour)**) | | |
| Relative costs of | 0.33 | 1 |
| the epitaxial | | |
| coating per wafer | | |

**)for a 3-chamber single-wafer reactor
***)3 μm standard epitaxy

1. A semiconductor wafer, comprising a substrate wafer made of silicon and an epitaxial layer deposited thereon, characterized in that the substrate wafer has a resistivity of from 0.1 to 50 Ωcm, an oxygen concentration of less than 7.5*10¹⁷ atcm⁻³ and a nitrogen concentration of from 1*10¹³ to 5*10¹⁵ atcm⁻³, and the epitaxial layer has a thickness of from 0.2 to 1.0 μm and has a surface on which fewer than 30 LLS defects with a size of more than 0.085 μm can be detected.

2. The semiconductor wafer as claimed in claim 1, characterized in that the oxygen concentration of the substrate wafer is less than 6.5*10¹⁷ atcm⁻³.

3. The semiconductor wafer as claimed in claim 1 or claim 2, characterized in that the nitrogen concentration of the substrate wafer lies in a range of from 1*10¹⁴ to 5*10¹⁴ atcm⁻³.

4. A process for producing a semiconductor wafer with an epitaxial layer by depositing the layer on a substrate wafer made of silicon, characterized by a sequence of steps comprising:
the provision of the substrate wafer, the substrate wafer having a resistivity of from 0.1 to 50 Ωcm, an oxygen concentration of less than 7.5*10¹⁷ atcm⁻³ and a nitrogen concentration of from 1*10¹³ to 5*10¹⁵ atcm⁻³;
the heating of the substrate wafer in a deposition reactor to a deposition temperature of at least 1120° C.; and
immediately after the deposition temperature has been reached, the deposition of the epitaxial layer with a thickness of from 0.2 to 1.0 μm.

5. The process as claimed in claim 4, characterized in that a single crystal is pulled from a melt in accordance with the Czochralski process, and at least 90 min elapse before the single crystal has passed through the temperature range from 1050 to 900° C., the single crystal serving as a source for the provision of the substrate wafer, and the deposition temperature during the deposition of the epitaxial layer is from 1120 to 1170° C.

6. The process as claimed in claim 5, characterized in that the deposition temperature is from 1130 to 1160° C.

7. The process as claimed in claim 4, characterized in that a single crystal is pulled from a melt in accordance with the Czochralski process and not more than 40 min elapse before the single crystal, with application of forced cooling, has passed through the temperature range from 1050 to 900° C., the single crystal serving as a source for the provision of the substrate wafer, and the deposition temperature during the deposition of the epitaxial layer is from 1120 to 1200° C.

8. The process as claimed in claim 7, characterized in that the deposition temperature is from 1130 to 1190° C.

9. The process as claimed in one of claims 4 to 8, characterized in that the substrate wafer is heated to the deposition temperature in a gas atmosphere, the gas atmosphere being selected from a group of gases which includes hydrogen, argon, helium and any desired mixtures of the gases mentioned.

10. The process as claimed in one of claims 4 to 9, characterized in that the epitaxial layer is deposited in a deposition atmosphere containing a deposition gas and a dopant gas, the deposition gas being selected from a group of gases which includes trichlorosilane, silane, dichlorosilane, tetrachlorosilane and any desired mixtures of the gases mentioned, and the dopant gas being selected from a group of gases which includes diborane, phosphine and arsine.

11. The process as claimed in one of claims 4 to 10, characterized in that the epitaxial layer is deposited within a deposition time of from 1 to 10 s.

12. The process as claimed in one of claims 4 to 11, characterized in that the deposition reactor is subjected to cleaning with an etching gas or plasma at the earliest after an epitaxial layer has been deposited on 50 substrate wafers in succession.
